(19) United States
(12) Patent Application Publication
(10) Pub. No.: US 2026/0282332 A1
(43) Pub. Date: Sep. 17, 2026

(54) SEMICONDUCTOR DEVICE AND FABRICATING METHOD THEREOF

(71) Applicant: Fujian Jinhua Integrated Circuit Co., Ltd., Quanzhou City (CN)

(72) Inventors: Yidan Zhang, Quanzhou City (CN); Yifei Yan, Quanzhou City (CN); JIANSHAN WU, Quanzhou City (CN); Dunshang Jin, Quanzhou City (CN); Choukun Tang, Quanzhou City (CN); Xu Liu, Quanzhou City (CN)

(73) Assignee: Fujian Jinhua Integrated Circuit Co., Ltd., Quanzhou City (CN)

(21) Appl. No.: 19/361,021

(22) Filed: Oct. 17, 2025

(30) Foreign Application Priority Data
Mar. 14, 2025 (CN) 202510307672.5

(51) Int. Cl. H10B 12/00

(52) U.S. Cl. CPC H10B 12/482; H10B 12/02; H10B 12/315

(57) ABSTRACT

The present disclosure provides a semiconductor device and a fabricating method thereof, and the semiconductor device includes a substrate, a plurality of bit lines, a bit line spacer, and at least one filling layer. The bit lines extend in a first direction and is separately disposed on the substrate. The bit lines include a plurality of second bit lines and at least one first bit line disposed at one side of the second bit lines. The bit line spacer is disposed on a sidewall of each second bit line and the at least one first bit line. The at least one filling layer extends in the first direction and is disposed in the at least one first bit line, and which includes a material being the same as a material of at least a portion of the bit line spacer.

### CROSS REFERENCE TO RELATED APPLICATION

This application claims the benefit of Chinese Patent Application No. 2 02510307672.5 filed on Mar. 14, 2025, which is incorporated herein by reference.

### BACKGROUND OF THE INVENTION

### 1. FIELD OF THE INVENTION

The present disclosure generally relates to a semiconductor device and a fabricating method thereof, and more particularly to a semiconductor device having a bit line structure and a fabricating method thereof.

### 2. DESCRIPTION OF THE PRIOR ART

With the trend of miniaturization of various electronic products, the design of semiconductor devices must also meet the requirements of high integration and high density. For dynamic random access memories (DRAMs) having recessed gate structures, current leakage of capacitor structures can be reduced due to longer carrier channel length in the same semiconductor substrate. Therefore, under the current mainstream of development trend, they have gradually replaced the DRAMs having only planar gate structures. In general, a DRAM with a recessed gate structure includes a huge number of memory cells, which form an array region for storing data. Each of the memory cells includes a transistor component and a capacitor component connected in series to receive voltage signals from bit lines (BLs) and word lines (WLs). To meet the demands on features of products, it is still necessary to keep raising the intensity of the memory cells in the array region. As a result, the manufacturing process and the design would become more and more critical, and the complexity would be higher and higher. Therefore, the prior art techniques or the conventional structures need to be further improved to effectively improve the performance and reliability of related memory devices.

### SUMMARY OF THE INVENTION

An object of the present invention is to provide a semiconductor device, where a filling portion is additionally disposed within a bit line in a peripheral region, so as to improve the structural integrity of each bit line in a cell region. Accordingly, the semiconductor device of the present invention is allowable to gain better component structure and function, thereby enhancing an operating performance thereof.

An object of the present invention is to provide a fabricating method of a semiconductor device, in which a filling portion is additionally formed within a bit line in a peripheral region, so as to improve the structural integrity of each bit line in a cell region. Also, the formation of the filling portion enables to be integrated with the process of a bit line spacer. Accordingly, the semiconductor device with better component structure and function will be fabricated through the method of the present invention under a simplified process, without performing additionally process.

In order to achieve the above objects, an embodiment of the present invention provides a semiconductor device including a substrate, a plurality of bit lines, a bit line spacer, and at least one filling layer. The plurality of bit lines extends in a first direction and is separately disposed on the substrate. The plurality of bit lines includes at least one first bit line and a plurality of second bit lines, and the at least one first bit line is disposed at one side of the plurality of second bit lines. The bit line spacer is disposed on a sidewall of each of the plurality of second bit lines and a sidewall of the at least one first bit line. The at least one filling layer extends in the first direction and is disposed in the at least one first bit line, wherein the at least one filling layer includes a material being the same as that of at least a portion of the bit line spacer.

In order to achieve the above objects, an embodiment of the present invention provides a semiconductor device including a substrate, a plurality of bit lines, and a filling portion. The plurality of bit lines is separately disposed on the substrate and includes at least one first bit line and a plurality of second bit lines. The at least one first bit line is disposed at one side of the plurality of second bit lines and includes a conductor layer. The filling portion is disposed in the at least one first bit line, wherein a bottom surface of the filling portion is higher than a bottom surface of the conductive layer in a vertical direction.

In order to achieve the above objects, an embodiment of the present invention provides a fabricating method of a semiconductor device including the following steps. A substrate is provided, and a plurality of bit lines is formed on the substrate. The plurality of bit lines parallel extends in a first direction and includes at least one first bit line and a plurality of second bit lines, and the at least one first bit line is disposed at one side of the plurality of second bit lines. The bit line spacer is disposed on a sidewall of each of the plurality of second bit lines and a sidewall of the at least one first bit line. The at least one filling layer is formed within the at least one first bit line. The at least one filling layer extends in the first direction and includes a material being the same as that of at least a portion of the bit line spacer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 5 are schematic diagrams illustrating a semiconductor device according to a first embodiment in the present disclosure, in which:

FIG. 1 shows a top view of a semiconductor device in the first embodiment of the present disclosure;

FIG. 2 shows a cross-sectional view taken along a cross line A-A’ in FIG. 1;

FIG. 3 shows a cross-sectional view taken along a cross line B-B’ in FIG. 1;

FIG. 4 shows a cross-sectional view taken along a cross line C-C’ in FIG. 1; and

FIG. 5 shows a cross-sectional view taken along a cross line D-D’ in FIG. 1.

FIG. 6 is a schematic diagram illustrating a semiconductor device according to a preferred embodiment in the present disclosure.

FIG. 7 to FIG. 12 are schematic diagrams illustrating a method of fabricating the semiconductor device according to a preferred embodiment of the present invention, wherein:

FIG. 7 is a top view illustrating of a semiconductor device after forming a mask layer;

FIG. 8 shows a cross-sectional view taken along a cross line A-A’ in FIG. 7;

FIG. 9 is a top view illustrating of a semiconductor device after performing a patterning process;

FIG. 10 shows a cross-sectional view taken along a cross line A-A’ in FIG. 9;

FIG. 11 is a top view illustrating of a semiconductor device after forming bit lines and recesses; and

FIG. 12 shows a cross-sectional view taken along a cross line A-A’ in FIG. 11.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

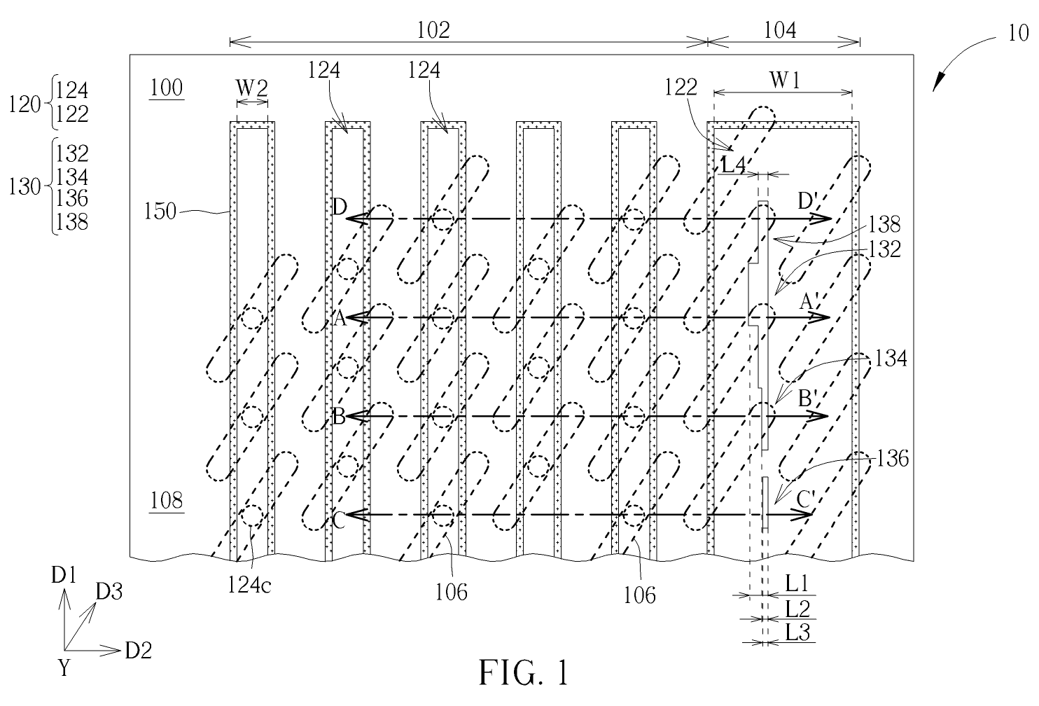

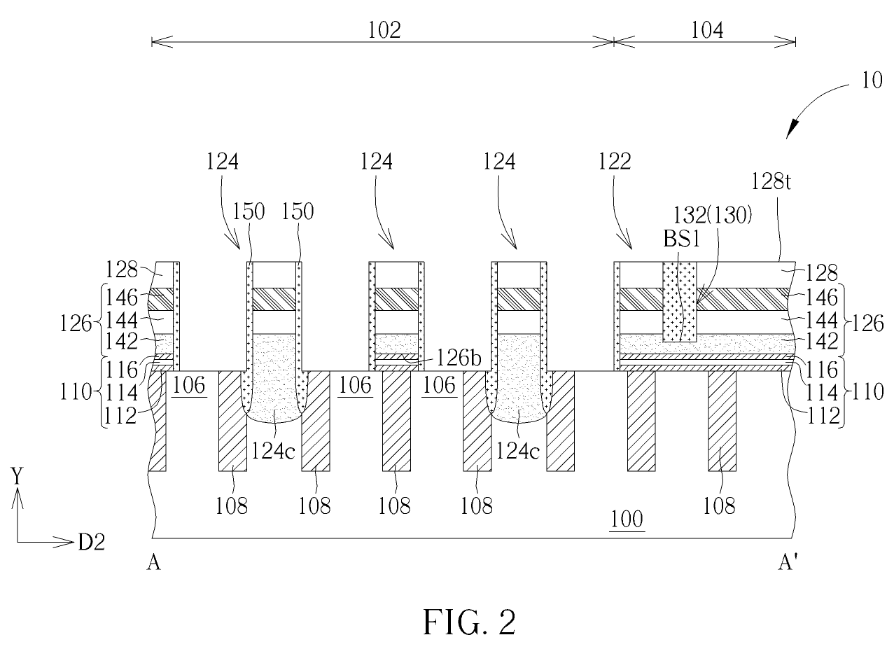

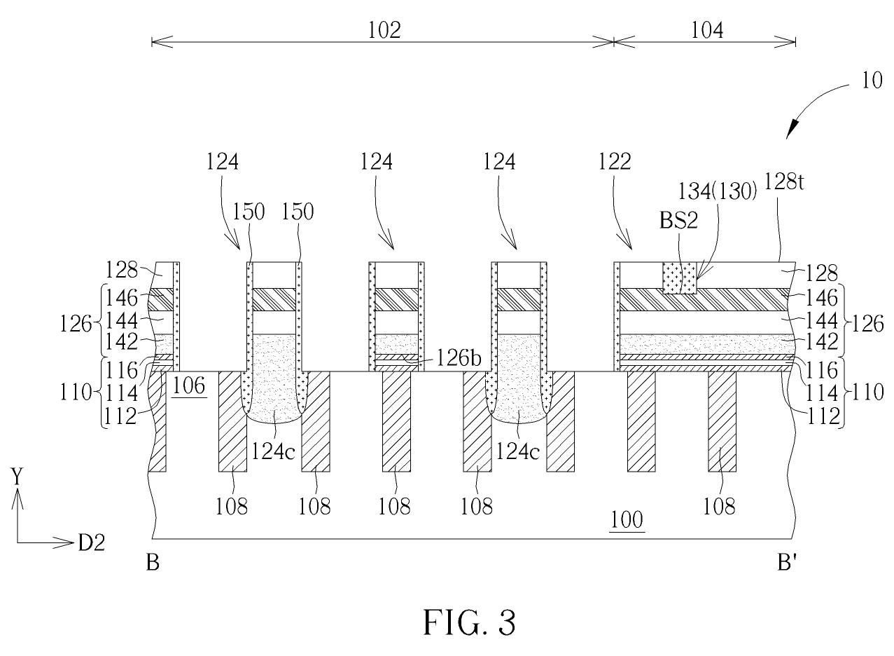

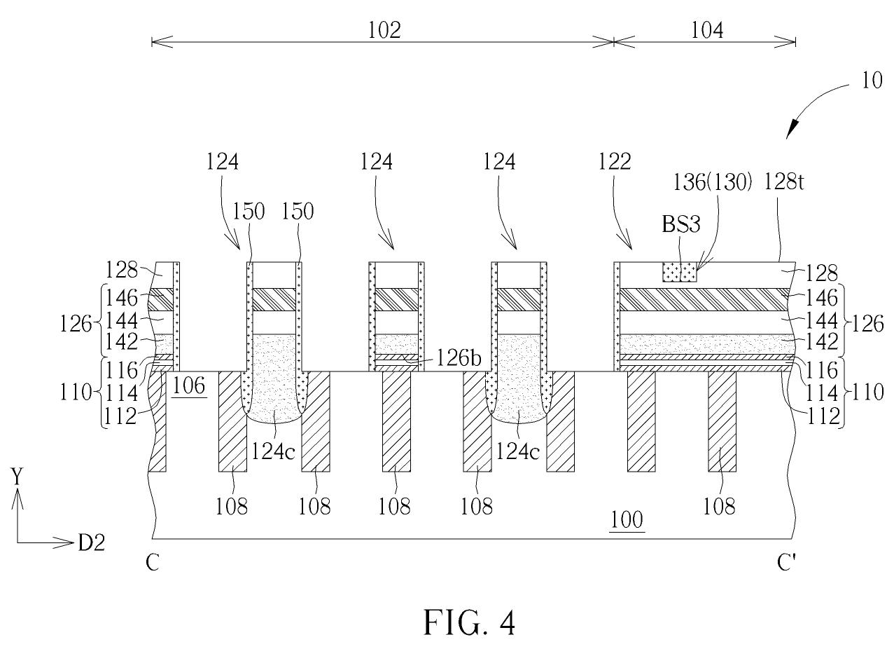

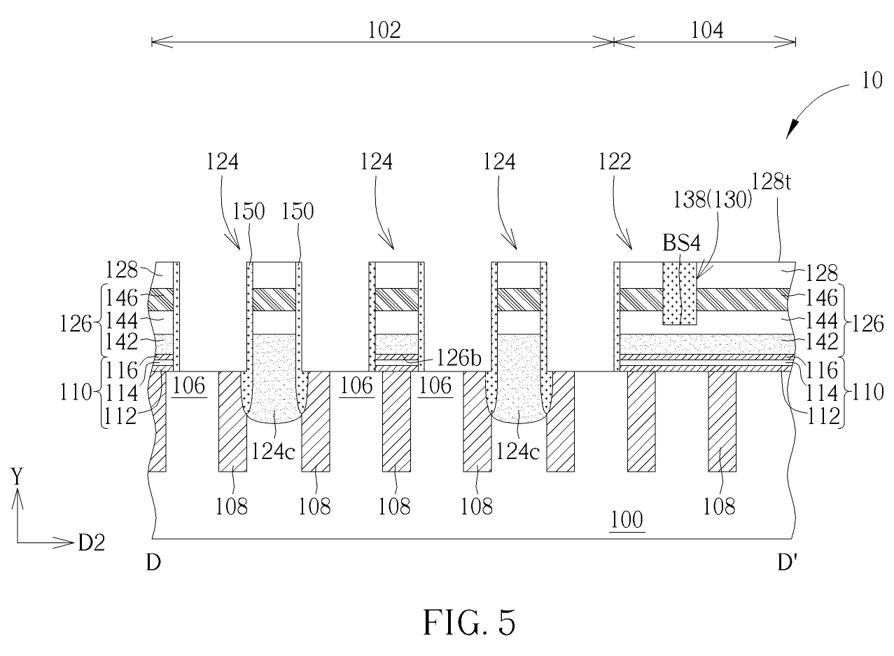

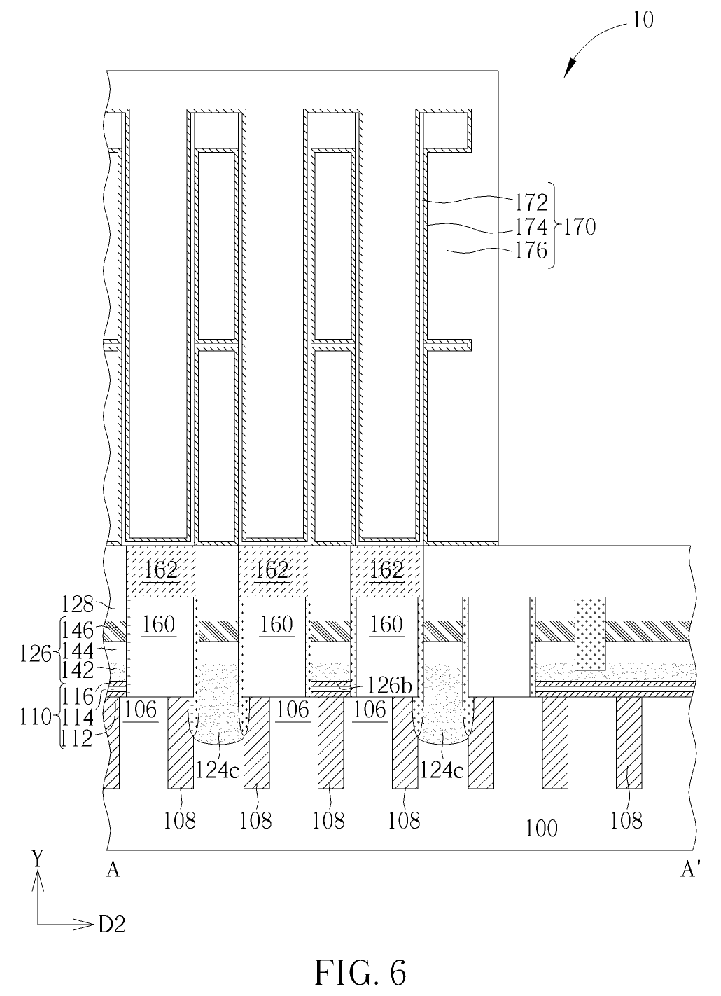

Please refer to FIG. 1 to FIG. 5, which illustrate a semiconductor device 10 according to a first embodiment of the present disclosure, wherein FIG. 1 showing a top view of the semiconductor device 10, and FIG. 2, FIG. 3, FIG. 4 and FIG. 5 respectively showing a cross-sectional view of the semiconductor device 10. Firstly, as shown in FIG. 1, the semiconductor device 10 includes a substrate, a plurality of bit lines 120, a bit line spacer 150 and at least one filling layer 130. The substrate 100 for example includes a silicon substrate, a silicon containing substrate or a silicon on insulator (SOI) substrate, and a cell region 102 where the component integration is relatively higher, and a peripheral region 104 where the component integration is relatively lower, are both defined on the substrate 100. Precisely, the bit lines 120 are separately disposed on the substrate 100, with the bit lines 120 respectively extending in a first direction D1 and including at least one first bit line 122 and a plurality of second bit lines 124. The at least one first bit line 122 is disposed at one side of all of the second bit lines 124, in a second direction D2 perpendicular to the first direction D1. The bit line spacer 150 is disposed around a sidewall of each of the second bit lines 124 and a sidewall of the at least one first bit line 122.

It is noted that, the at least one filling layer 130 also extends in the first direction D1, and which is disposed in the at least one first bit line 122. The at least one filling layer 130 for example includes a material being the same as at least a portion of the bit line spacer 150, for example including an insulating material like silicon oxide, silicon oxynitride, silicon nitride, silicon carbonitride or a combination thereof, but not limited thereto. In one embodiment, at least one filling layer 130 and the bit line spacer 150 for example respectively includes a monolayer structure as shown in FIG. 1, with the monolayer structure of the at least one filling layer 130 and the bit line spacer 150 including the same insulating material. Otherwise, in another embodiment, the bit line spacer 150 for example includes a multilayer structure (not shown in the drawings), and the at least one filling layer 130 optionally includes a monolayer structure having a material the same as a portion of the multilayer structure of the bit line spacer 150, or a multilayer structure (not shown in the drawings) having materials completely the same or partially the same as the multilayer structure of the bit line spacer 150. Accordingly, through arranging the at least one first bit line 122 within the peripheral region 104, it is allowable to effectively improve the component integrity of each second bit line 124 disposed within the cell region 102. Then, the semiconductor device 10 of the present embodiment will enable to gain better component structure and functions, so as to enhance the operating performance of the semiconductor device 10.

Precisely speaking, the at least one filling layer 130 further includes a plurality of filling portions 132, 134, 136, 138 respectively extending in the first direction D1, and each of the filling portions 132, 134, 136, 138 includes a length L1, L2, L3, L4 different from each other. In one embodiment, at least two filling portions such as the filling portions 132, 134, 138 are in connection with each other, or at least two filling portions such as the filling portions 136, 132 are separately disposed from each other, but not limited thereto. Further in view of FIG. 1, at least one shallow trench isolation (STI) 108 is further disposed within the cell region 102 and the peripheral region 104, to define a plurality of active areas (AAs) 106 in the substrate 100. Each of the active areas 106 for example extends in a third direction D3 being not perpendicular to the first direction D1 and the second direction D2, so that, each second bit line 124 within the cell region 102 will simultaneously intersect at least two corresponding active areas 106, to directly contact each corresponding active area 106 through a bit line contact (BLC) disposed underneath. Accordingly, each second bit line 124 is electrically connected to a transistor component (not shown in the drawings) disposed within the substrate 100, for receiving or transmitting signals from the transistor component. In one embodiment, each bit line 124 for example includes the same length W2 in the second direction D2, and a length W1 of the at least one first bit line 122 in the second direction D2 is larger than the length W2, preferably being about 2 to 10 times of the length W2, but not limited thereto.

On the other hand, in view of the cross-sectional views as shown in FIG. 2 to FIG. 5, a plurality of the shallow trench isolations 108 and the active areas 106 are alternately disposed in the substrate 100, and the at least one first bit line 122 and each second bit line 124 are for example separately disposed on the substrate 100, with the at least one first bit line 122 intersecting at least two active areas 106 within the peripheral region 104 in the second direction D2. The bit line spacer 150 is disposed on two opposite sidewalls of each second bit line 124 and the at least one first bit line 122. It is noted that, the at least one filling layer 130 is disposed in the at least one first bit line 122, to improve the structural integrity of the second bit line 124 disposed adjacent thereto. The filling portions 132, 134,136, 138 of the at least one filling layer 130 each includes a bottom surface BS1, BS2, BS3, BS4, with the bottom surfaces BS1, BS2, BS3, BS4 being not at the same plane. That is, any two of the filling portions such as the filling potions 132, 134, or the filling portions 136, 138 may have different extending depths in the at least one first bit line 122.

Precisely speaking, the at least one first bit line 122 and the second bit lines 124 for example each includes a conductive layer 126 disposed on a dielectric layer 110, and the conductive layer 126 may further include a semiconductor layer 142 (for example including a semiconductor material like doped polysilicon, doped silicon or doped silicon phosphorus), a barrier layer 144 (for example including a conductive barrier material like titanium and/or titanium nitride, tantalum and/or tantalum oxide), and a metal layer 146 (for example including a metal material with a low resistivity like copper, aluminum or tungsten) stacked in sequence in a vertical direction Y, and the bottom surfaces BS1, BS2, BS4 of the filling portions 132, 134, 138 are respectively disposed in the semiconductor layer 142, the metal layer 146 and the barrier layer 144 of the at least one first bit line 122, as shown in FIG. 2 to FIG. 5, but not limited thereto. In one embodiment, a covering layer 128 is further disposed on the at least one first bit line 122 and each second bit line 124, with the covering layer 128 for example including an insulating material like silicon nitride, silicon carbonitride or silicon oxynitride, and the bottom surface BS3 of the filling portion 136 is disposed in the covering layer 128. The dielectric layer 110 for example includes a silicon oxide 112, a silicon nitride 114, and a silicon oxide 116 stacked in sequence, to obtain an oxide-nitride-oxide (ONO) structure.

Further in view of FIG. 2 to FIG. 5, the bottom surface BS1 of the filling portion 132 is for example disposed between a top surface and a bottom surface of the semiconductor layer 142 of the at least one first bit line 122, in the vertical direction Y, the bottom surface BS2 of the filling portion 134 is for example disposed between a top surface and a bottom surface of the metal layer 146 of the at least one first bit line 122, in the vertical direction Y, the bottom surface BS3 of the filling portion 136 is for example disposed between a top surface and a bottom surface of the covering layer 128 over the at least one first bit line 122, in the vertical direction Y, and the bottom surface BS4 of the filling portion 138 is for example disposed between a top surface and a bottom surface of the barrier layer 144 of the at least one first bit line 122, in the vertical direction Y, but not limited thereto. Preferably, the bottom surfaces BS1, BS2, BS3, BS4 of each of the filling portions 132, 134, 136, 138 are higher than a bottom surface 126b of the conductive layer 126 (namely the bottom surface of the semiconductor layer 142), and lower than the top surface 128t of the covering layer 128. Also, the filling portions 132, 134, 138 having a relative larger length L1, L2, L4 in the second direction D2 each includes a relative greater depth in the at least one first bit line 122, in the vertical direction Y, as shown in FIG. 1 to FIG. 5, but not limited thereto. That is, while the length L1 of the filling portion 132 is larger than the length L2 of the filling portion 134, the length L3 of the filling portion 136, or the length L4 of the filling portion 138, the depth of the filling portion 132 in the at least one first bit line 122 is correspondingly greater than the depth of the filling portion 134 or 138 in the at least one first bit line 122 or the depth of the filling portion 136 in the covering layer 128. In addition, while the length L4 of the filling portion 138 is larger than the length L2 of the filling portion 134, and the length L2 of the filling portion 134 is larger than the length L3 of the filling portion 136, the depth of the filling portion 138 in the at least one first bit line 122 is greater than the depth of the filling portion 134 in the at least one first bit line 122, and the depth of the filling portion 134 in the at least one first bit line 122 is greater than the depth of the filling portion 136 in the covering layer 128.

It is also noted that, the at least one filling layer 130 includes the material the same as at least a portion of the bit line spacer 150, so that the formations of the at least one filling layer 130 and the bit line spacer 150 may be performed through the same process. For example, in one embodiment, the bit line spacer 150 for example includes a monolayer insulating material as shown in FIG. 1, and the at least one filling layer 130 may also include the monolayer insulating material the same as that of the bit line spacer 150. However, in another embodiment, the bit line spacer 150 may include a multilayer insulating material (not shown in the drawings), for example including a first spacer (not shown in the drawings), a second spacer (not shown in the drawings) and a third spacer (not shown in the drawings) stacked in sequence and including different insulating materials, and the at least one filling layer 130 will optionally include a monolayer insulating layer having the same material as that of the first spacer, or a multilayer insulating layer having the same materials as that of the first spacer and the second spacer, or the same materials as that of the first spacer, the second spacer and the third spacer, but not limited thereto.

Due to clearly illustrate the arrangements of above components, some components are omitted from the drawings of the present embodiment, and however, people skilled in the art should fully realize the semiconductor device 10 may further include any required components according to practical requirements. For example, in one preferably embodiment, the semiconductor device 10 may further include a plurality of word lines (not shown in the drawings), a plurality of storage node contacts 160, a plurality of storage node pads 162, and a capacitor structure 170 (including a plurality of bottom electrodes 172, a capacitor dielectric layer 174, and a top electrode 176 stacked in sequence) disposed within the cell region 102. The word lines are parallelly extended in the second direction D2 perpendicular to the second bit lines 124. The storage node contacts 160 are alternately arranged with the second bit lines 124 in the second direction D2, to physically contact the storage node pads 162 respectively. Accordingly, each of the storage node contacts 160 is electrically connected to the corresponding active area 106 and one bottom electrode 172 disposed on the corresponding storage node pad 162, for receiving and transmitting a voltage signal from the substrate 100 (namely, a source or drain of the transistor component within the substrate 100).

In order to make those skilled in the art easily understand the semiconductor device 10 according to the present invention, a manufacturing process of the semiconductor device 10 according to the present application will be further described hereinafter.

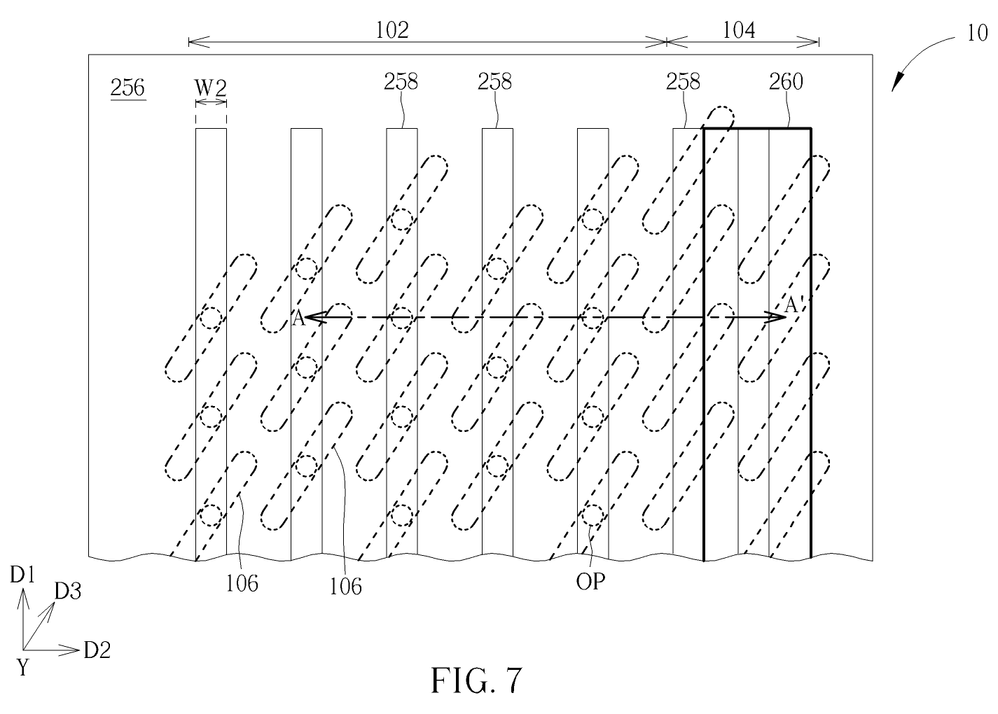

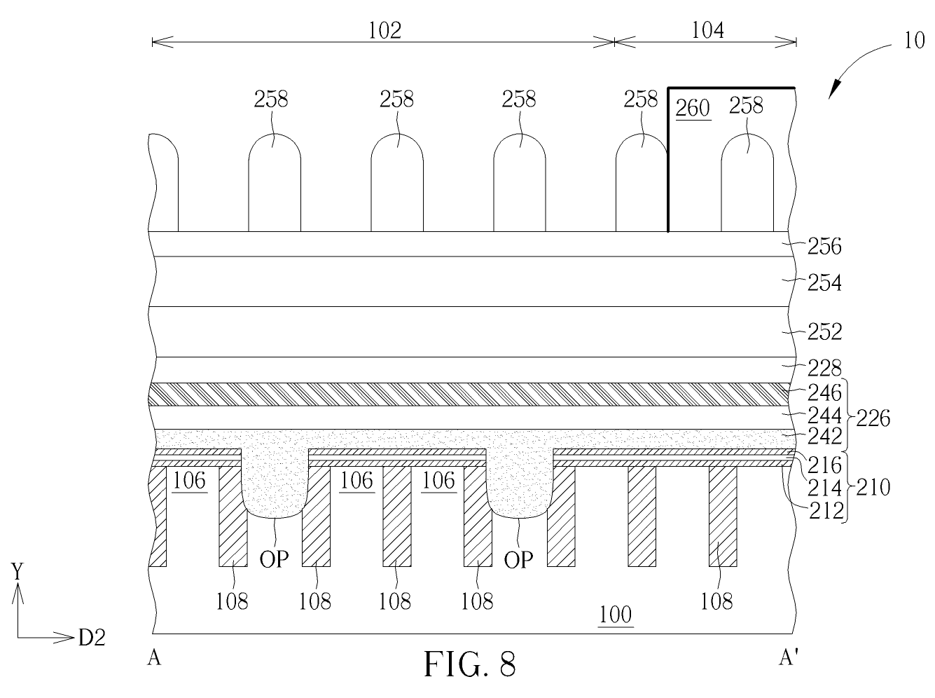

Please refer to FIGS. 7 to 12, which are schematic diagrams illustrating a fabricating method of the semiconductor device 10 according to a preferred embodiment of the present disclosure. Firstly, as shown in FIG. 7, and FIG. 8, a substrate 100 is provided, and the cell region 102 where the component integration is relatively higher and the peripheral region 104 where the component integration is relatively lower, are respectively defined in the substrate 100. Also, the at least one shallow trench isolation 108 is formed in the substrate 100, to define the active areas 106 in the cell region 102 and in the peripheral region 104. Precisely speaking, each of the active areas 106 parallel and separately extends in the third direction D3 into a specific arrangement, such as an array arrangement shown in FIG. 7, but not limited thereto. In one embodiment, the formation of the active areas 106 and the at least one shallow trench isolation 108 is accomplished by but not limited to the following processes. At first, a bulk silicon (not shown in the drawings) is provided, and a mask layer (not shown in the drawings) is formed on the bulk substrate, with the mask layer including a plurality of patterns for defining the active areas 106. Then, an etching process is performed on the bulk silicon, through the mask layer, to partially remove the bulk substrate to form the active areas 106 and at least one shallow trench (not shown in the drawings) surrounding the active areas 106, and an insulating material (not shown in the drawings) such as silicon oxide, silicon nitride or silicon oxynitride is formed in the shallow trench, to form the substrate 100 and the at least one shallow trench isolation 108 within the substrate 100. Furthermore, in another embodiment, a self-aligned double patterning (SADP) process or a self-aligned reverse patterning (SARP) process may be carried out to form a patterned mask for defining the active areas 106, but not limited thereto.

Next, a dielectric material layer 210 is formed on the substrate 100, and a patterning process is performed through a mask layer (not shown in the drawings), to partially remove the dielectric material layer 210 and the active areas 106 underneath, to form a plurality of contact openings OP. In one embodiment, the dielectric material layer 210 for example includes an silicon oxide material layer 212, a silicon nitride material layer 214 and an silicon oxide material layer 216 stacked in sequence, as shown in FIG. 8. Then, a deposition process is performed, to sequentially form a conductive material layer 226 and a covering material layer 228 on the dielectric material layer 210, with the covering material layer 228 for example including an insulating material like silicon oxide, silicon oxynitride or silicon carbonitride. The conductive material layer 226 for example includes a semiconductor material layer 242 (for example including a semiconductor material like doped polysilicon doped silicon or doped silicon phosphorus), a barrier material layer 244 (for example including a conductive barrier material like titanium and/or titanium nitride, tantalum and/or tantalum oxide), and a metal material layer 246 (for example including a metal material with a low resistivity like copper, aluminum or tungsten) as shown in FIG. 8, and a portion of the semiconductor material layer 242 is further filled in the contact openings OP. Then, a mask structure and a photoresist layer 260 are further formed on the covering material layer 228, with the mask structure further including an insulating layer 252, a sacrificial layer 254 (for example including an organic dielectric material), a silicon-containing hard mask (SHB) layer 256 and a patterned mask layer 258 stacked in sequence.

Precisely speaking, the patterned mask layer 258 includes a plurality of mask patters for defining the bit lines 120, with the mask patterns being separately arranged within the cell region 102 and within the peripheral region 104, and the photoresist layer 260 is formed over the SHB layer 256, with the SHB layer 256 being formed within the peripheral region 104 only, to overlay a portion of the mask patterns and to expose another portion of the mask patterns. It is noted that, through adjusting the location of the photoresist layer 260, the photoresist layer 260 of the present embodiment will cover at least one of the mask patterns within the peripheral region 104, with another one of the mask patterns within the peripheral region 104 being exposed therefrom. In other words, the mask patterns formed within the cell region 102 will not be blocked by the photoresist layer 260, so that, each of the mask patterns formed within the cell region 102 may obtain a complete pattern and outline thereby, without presenting in any incomplete pattern, as shown in FIG. 7 and FIG. 8. The photoresist layer 260 is directly in contact with a corresponding one of the mask patterns, with a sidewall of the photoresist layer 260 being vertical aligned with a sidewall of the corresponding one of the mask patterns, as shown in FIG. 7 and FIG. 8.

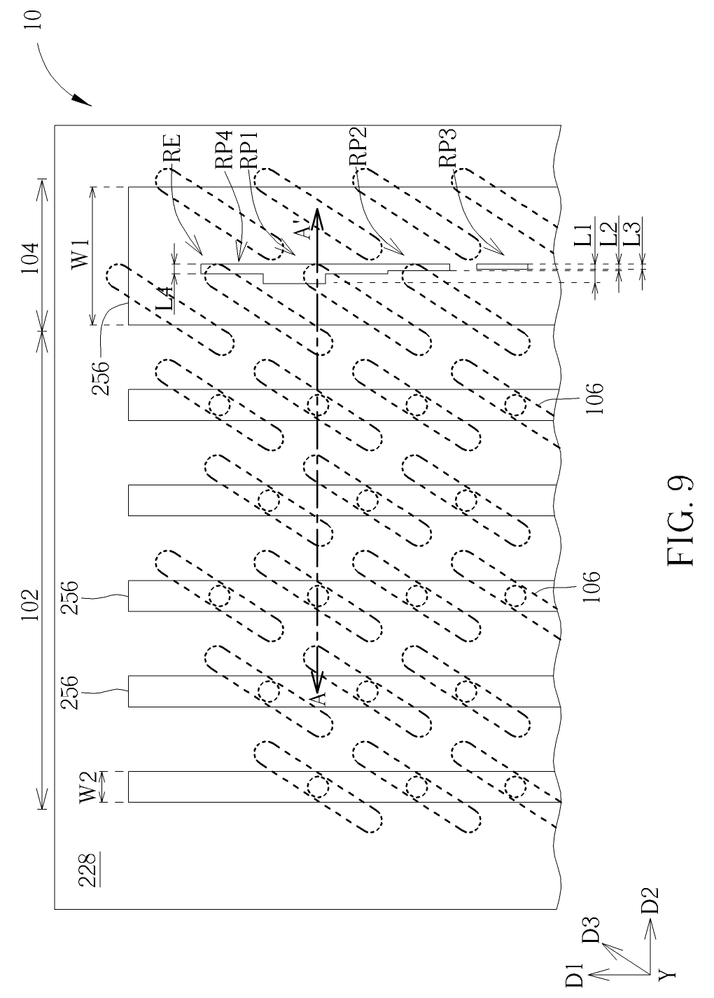

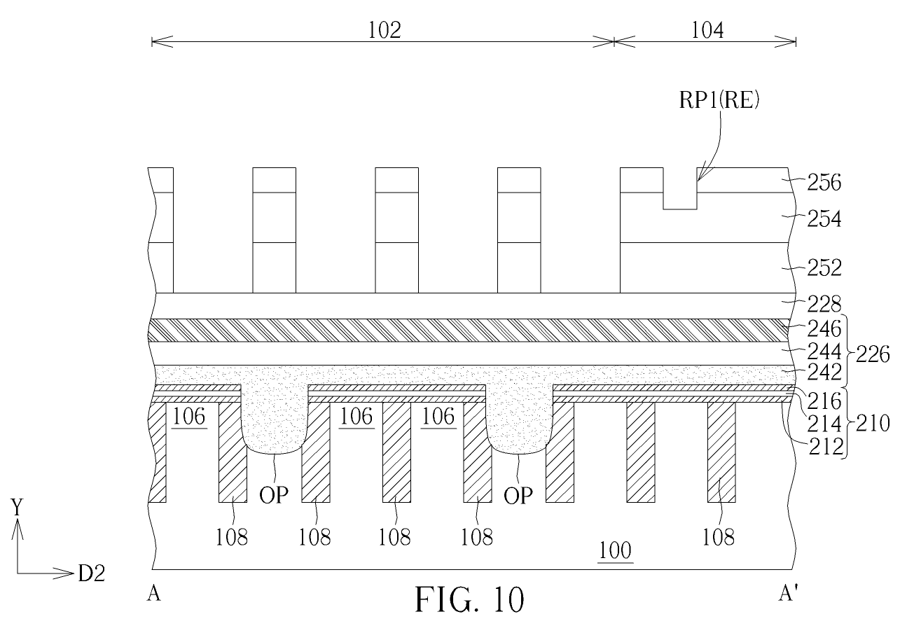

As shown in FIG. 9 and FIG. 10, a patterning process is performed through the another portion of the mask patterns of the patterned mask layer 258 and the photoresist layer 260, to partially remove the SHB layer 256, the sacrificial layer 254 and the insulating layer 252, and to simultaneously transfer patterns of the patterned mask layer 258 and the photoresist layer 260 into the SHB layer 256, the sacrificial layer 254 and the insulating layer 252 underneath, and then, the patterned mask layer 258 and the photoresist layer 260 are completely removed. After performing the patterning process, the mask patterns of the patterned mask layer 258 formed within the cell region 102 are completely transferred into the SHB layer 256, the sacrificial layer 254 and the insulating layer 252 underneath, to form the patterned SHB layer 256, the patterned sacrificial layer 254 and the patterned insulating layer 252 each having a relative smaller length W2 in the second direction D2. Meanwhile, the mask patterns of the patterned mask layer 258 formed within the peripheral region 104 and the photoresist layer 260 are together transferred into the SHB layer 256, the sacrificial layer 254 and the insulating layer 252 underneath, to form the patterned SHB layer 256, the patterned sacrificial layer 254 and the patterned insulating layer 252 each having a relative larger length W1 in the second direction D2, as shown in FIG. 9, but not limited thereto.

It is noted that, since the photoresist layer 260 as shown in FIG. 7 and FIG. 8 is formed adjacent to the corresponding one of the mask patterns of the patterned mask layer 258 in the peripheral region 104, the SHB layer 256, the sacrificial layer 254 and the insulating layer 252 in the cell region 102 will not be affected by the etchant performed in the peripheral region 104, during the patterning process. Then, the patterned SHB layer 256, the patterned sacrificial layer 254 and the patterned insulating layer 252 formed within the cell region 102 may each obtain the complete pattern and outline thereby. It is also noted that, while performing the patterning process through the mask patterns of the patterned mask layer 258 and the photoresist layer 260 formed within the peripheral region 104, at least one recess RE can be further formed within the peripheral region 104, at the boundary between the photoresist layer 260 and the corresponding one of the mask patterns of the patterned mask layer 258. The at least one recess RE is formed by adjusting the etching conditions like the etching selectivity and/or the etching direction of the etchant performed in the peripheral region 104, and further etching the SHB layer 256 under the boundary between the photoresist layer 260 and the corresponding one of the mask patterns of the patterned mask layer 258.

Precisely speaking, the at least one recess RE is formed along a side of the photoresist layer 260 extending in the first direction D1, and which may include various lengths L1, L2, L3, L4 in the second direction D2 and/or different depths in the vertical direction Y by adjusting the etching conditions like the etching selectivity or the etching direction. In one embodiment, the at least one recess RE for example includes a plurality of recessing portions RP1, PR2, PR3, PR4 each having a different length L1, L2, L3 or L4, as shown from a top view as shown in FIG. 9, and each of the recessing portions PR1, PR2, PR3 and PR4 may be optionally in connection or separated from each other. Preferably, the recessing portion PR1 with the relative larger length L1 includes the relative greater depth, so that, the recessing portion PR1 of the at least one recess RE is extended from the SHB layer 256 into a portion of the sacrificial layer 254, in the vertical direction Y, as shown in FIG. 10. On the other hand, the recessing portions PR2, PR3, PR4 each having the relative smaller length L2, L3, or L4 will have a relative lower depth (not shown in the drawings) in the vertical direction Y, but not limited thereto.

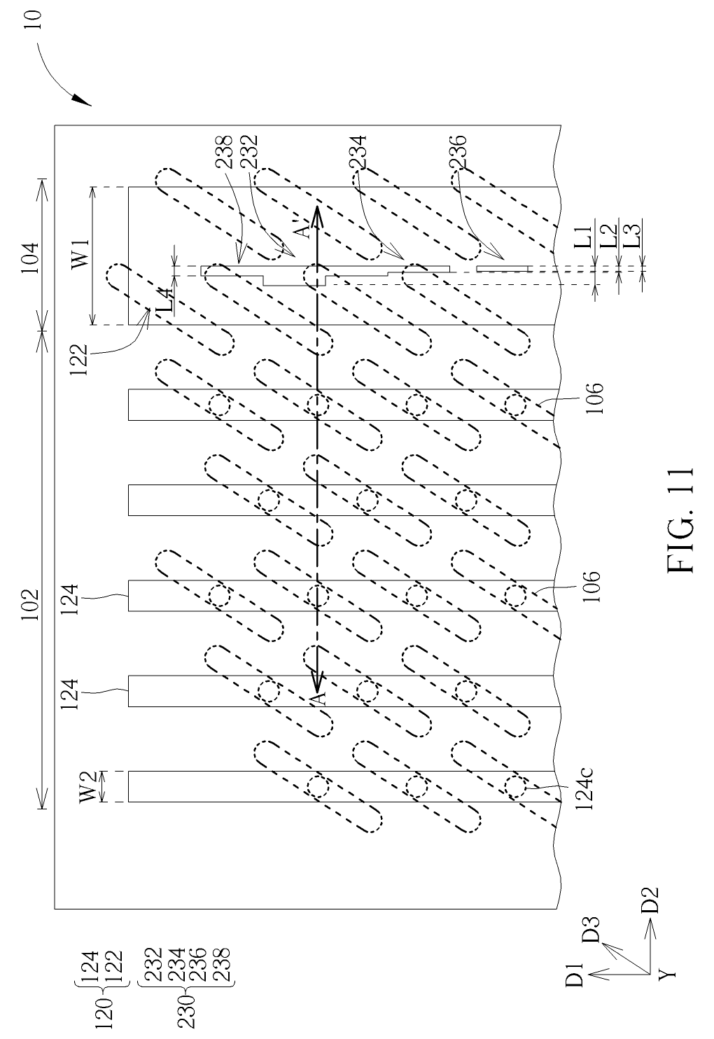

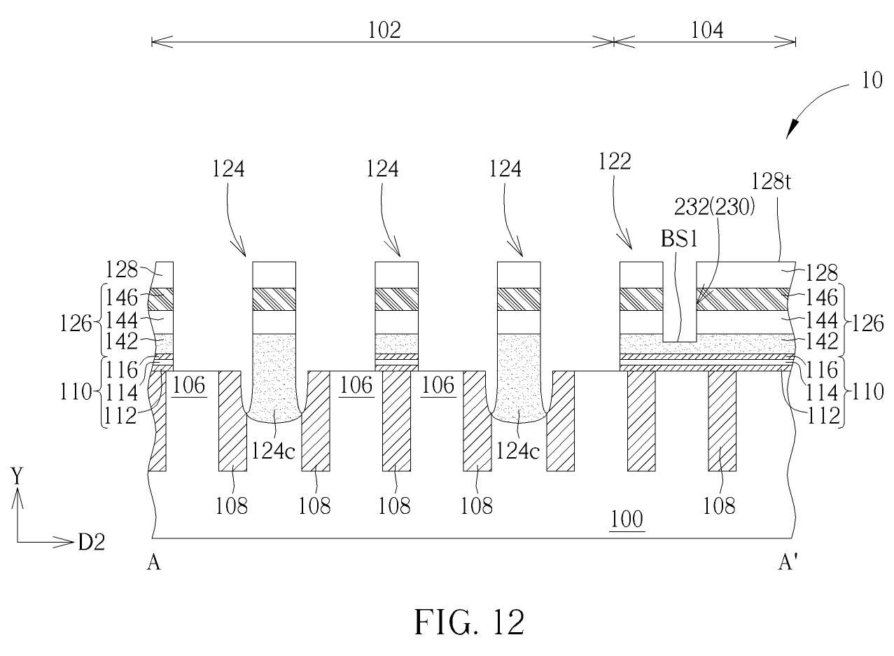

As shown in FIG. 11 and FIG. 12, an etching process is performed through the patterned SHB layer 256, the patterned sacrificial layer 254, and the patterned insulating layer 252 as an etching mask, to partially remove the covering material layer 228, the metal material layer 246, the barrier material layer 244, the semiconductor material layer 242, the silicon oxide material layer 212, the silicon nitride material layer 214 and the silicon oxide material layer 216 under the patterned insulating layer 252, and to pattern the covering material layer 228, the metal material layer 246, the barrier material layer 244 and the semiconductor material layer 242 as shown in FIG. 10 into the second bit lines 124 (each including the semiconductor layer 142, the barrier layer 144 and the metal layer 146 stacked in sequence) formed within the cell region 102, the at least one first bit line 122 (including the semiconductor layer 142, the barrier layer 144 and the metal layer 146 stacked in sequence) formed within the peripheral region 104, and the covering layer 128, and to pattern the silicon oxide material layer 212, the silicon nitride material layer 214 and the silicon oxide material layer 216 as shown in FIG. 10 into the dielectric layer 110 (including the silicon oxide layer 112, the silicon nitride layer 114 and the silicon oxide layer 116 stacked in sequence). Meanwhile, while the second bit lines 124 are formed, the semiconductor material layer 242 filled in the contact openings OP will therefore form the bit line contact 124c formed below each of the second bit lines 124.

Furthermore, while performing the etching process, the pattern of the at least one recess RE is transferred into the at least one first bit line 122, to form at least one recess 230 in the at least one first bit line 122. Precisely speaking, the at least one recess 230 is formed in the extending direction of the at least one first bit line 122 (namely the first direction D1), to include a pattern corresponding to that of the at least one recess RE as shown in FIG. 9, as shown in FIG. 11, but not limited thereto. In one embodiment, the at least one recess 230 is formed to include a plurality of recessing portions 232, 234, 236, 238 each having a different length L1, L2, L3 or L4 in the second direction D2, with each of the recessing portions 232, 234, 236, 238 for example being in connection with or separated from each other, but not limited thereto. For example, the recessing portions 232, 234 and 238 are in connection with each other, and the recessing portion 236 is separated from the recessing portions 232, 234 and 238, as shown in FIG. 11.

Preferably, the recessing portion 232 having the relative longer length L1 includes a relative greater depth in the vertical direction Y than that of the recessing portions 234, 236 and 238 each having the relative shorter length L2, L3, or L4. Accordingly, the recessing portion 232 may extend from the covering layer 128 into a portion of the semiconductor layer 142 of the at least one first bit line 122. That is, a bottom surface BS1 of the recessing portion 232 is for example formed within the semiconductor layer 142 of the at least one first bit line 122, as shown in FIG. 12, but not limited thereto. On the other hand, bottom surfaces (not shown in the drawings) of the recessing portions 234, 236 and 238 may be respectively formed at a plane being higher than the bottom surface BS1 of the recessing portion 232, for example being formed within the metal layer 146 or the barrier layer 144 of the at least one first bit line 233, or being formed within the covering layer 128, but not limited thereto. After that, at least one deposition process and at least one etching back process are performed, to form the bit line spacer 150 as shown in FIG. 1 to FIG. 5 on the sidewall of the at least one first bit line 122 and the sidewall of each second bit line 124.

In one embodiment, the formation of the at least one filling layer 130 and the formation of the bit line spacer 150 may but not limited to be accomplished by the same process, such that, the at least one filling layer 130 may include the insulating material and the film structure being the same as that of at least a portion of the bit line spacer 150. For example, while the bit line spacer 150 includes the monolayer insulating material as shown in FIG. 1, the at least one filling layer 130 fabricated through the same process may also include the monolayer insulating material the same as that of the bit line spacer 150. However, while the bit line spacer 150 includes a multilayer insulating material (not shown in the drawings), for example including a first spacer (not shown in the drawings), a second spacer (not shown in the drawings) and a third spacer (not shown in the drawings) stacked in sequence and including different insulating materials, and the at least one filling layer 130 fabricated through the same process may optionally include a monolayer insulating layer having the same material as that of the first spacer, or a multilayer insulating layer having the same materials as that of the first spacer and the second spacer, or the same materials as that of the first spacer, the second spacer and the third spacer, due to practical performing conditions of the deposition process, but not limited thereto. Although the bottom surfaces of the recessing portions 234, 236, 237 are not illustrated in the drawings of the present embodiment, people skilled in the art should easily realize that the forming positions of the bottom surfaces of each recessing portion 234, 236 or 238 based on the bottom surfaces BS2, BS3, or BS4 of the filling portion 134, 136, or 138 as shown in FIG. 2 to FIG. 5.

Through these performances, the fabrication of the semiconductor device 10 is accomplished. People skilled in the art should fully understand that the fabricating method of the semiconductor device 10 in the present embodiment may further include other processes, such as forming the plurality of word lines (not shown in the drawings) in the cell region 102, before forming the silicon oxide material layer 212, and forming the plurality of storage node contacts 160 in the cell region 102, after forming the bit line spacer 150 and the at least one filling layer 130. Accordingly, the word lines are parallelly extended in the second direction D2 being perpendicular to the second bit lines 124, and the storage node contacts 160 are formed to alternately arrange with the second bit lines 124 in the second direction D2, for electrically connecting to the corresponding active area 106 to receive and to transmit the voltage signals from the substrate 100 (namely, from the source or the drain of the transistor component). In this way, the semiconductor device 10 and the capacitor structure 170 formed above the semiconductor device 10 will together form the dynamic random access memory device, with the capacitor of the capacitor structure 170 and the transistor component within in the substrate 100 together serving as the minimum memory cell of the DRAM array to receive voltage information from the bit lines 120 and the word lines.

According to the fabricating method of the semiconductor device 10 in the present embodiment, the forming position of the photoresist layer 260 is adjusted to be closed to the corresponding one of the mask patterns of the patterned mask layer 258, while fabricating the bit lines 120. Accordingly, the formation of the second bit lines 124 within the cell region 102 will be free from being affected by the etchant performed on the photoresist layer 260 in the peripheral region 104, and also, the recess 230 is additionally formed in the first bit line 122, within the peripheral region 104. Then, a monolayer or multilayer insulating material is further filled in the recess 230, while forming the bit line spacer 150 in the subsequent process, to form the filling portion 130 in the first bit line 122. In this way, the filling portion 130 is allowable to be additionally formed in the first bit line 122 adjacent to the second bit line 124 in the cell region 102, without performing an additional process or using an additional photoresist, so as to improve the structural integrity of the second bit line 124 adjacent to the peripheral region 104. Thus, the semiconductor device 10 will therefore gain a better structural component and function, so as to enhance the operating performance thereby.

People skilled in the art should easily realize the semiconductor device in the present disclosure is not limited to the aforementioned embodiment, and may further include other examples to meet practical product requirements. For example, although the aforementioned embodiment is exemplified by disposing one filling layer 130 within the first bit line 122 (namely, with only one recess 230 being formed within the first bit line 122), the practical arrangement and the fabrication are not limited thereto. In another embodiment, a plurality of recesses (not shown in the drawings) is formed in the first bit line 122, followed by filling in the monolayer insulating material or the multilayer insulating material while forming the bit line spacer 150, to form a plurality of the filling layers (not shown in the drawings). The filling layers may each include a uniformed length (not shown in the drawings) in the second direction D2 and a uniformed depth in the vertical direction Y (not shown in the drawings), or may each include plural portions like the filling portions 132, 134, 136, 138 with various lengths L1, L2, L3, L4 in the second direction D2 and with different depths in the vertical direction Y as shown in FIG. 1 in the aforementioned embodiment, but not limited thereto. Accordingly, the semiconductor device of other embodiment will also gain the better structural component and function, to achieve the enhanced operating performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a plurality of bit lines extending in a first direction, and separately disposed on the substrate, the plurality of bit lines comprising at least one first bit line and a plurality of second bit lines, the at least one first bit line being disposed at one side of the plurality of second bit lines;
a bit line spacer, disposed on a sidewall of each of the plurality of second bit lines and a sidewall of the at least one first bit line; and
at least one filling layer, extending in the first direction and disposed in the at least one first bit line, wherein the at least one filling layer comprises a material being the same as a material of at least a portion of the bit line spacer.

2. The semiconductor device according to claim 1, wherein the at least one filling layer comprises a plurality of filling portions having different lengths in a second direction, and the second direction is perpendicular to the first direction.

3. The semiconductor device according to claim 2, wherein at least two of the plurality of filling portions are in connection with each other.

4. The semiconductor device according to claim 2, wherein at least two of the plurality of filling portions are separated disposed from each other.

5. The semiconductor device according to claim 2, wherein at least two of the plurality of filling portions comprise bottom surfaces not at the same plane.

6. A semiconductor device, comprising:
a substrate;
a plurality of bit lines separately disposed on the substrate, the plurality of bit lines comprising at least one first bit line and a plurality of second bit lines, the at least one first bit line being disposed at one side of the plurality of second bit lines, and comprising a conductor layer; and
a filling portion, disposed in the at least one first bit line, wherein a bottom surface of the filling portion is higher than a bottom surface of the conductive layer in a vertical direction.

7. The semiconductor device according to claim 6, wherein the conductive layer comprises a semiconductor layer, a barrier layer and a metal layer stacked in sequence.

8. The semiconductor device according to claim 7, wherein the bottom surface of the filling portion is disposed between a top surface and a bottom surface of the metal layer in the vertical direction.

9. The semiconductor device according to claim 7, wherein the bottom surface of the filling layer is disposed between a top surface and a bottom surface of the barrier layer in the vertical direction.

10. The semiconductor device according to claim 7, wherein the bottom surface of the filling layer is disposed between a top surface and a bottom surface of the semiconductor layer in the vertical direction.

11. The semiconductor device according to claim 6, further comprising:
a covering layer disposed on the conductive layer of each of the plurality of bit lines, wherein the bottom surface of the filling portion is disposed between a top surface and a bottom surface of the covering layer in the vertical direction.

12. The semiconductor device according to claim 6, further comprising:
a bit line spacer, disposed on a sidewall of each of the plurality of second bit lines and a sidewall of the at least one first bit line, wherein the filling portion comprises a material being the same as a material of at least a portion of the bit line spacer.

13. The semiconductor device according to claim 6, further comprising:
a plurality of active areas and a plurality of shallow trench isolations being alternately disposed in the substrate, wherein the at least one first bit line intersects at least two of the plurality of active areas in a horizontal direction.

14. A fabricating method of a semiconductor device, comprising:
providing a substrate;
forming a plurality of bit lines on the substrate, the plurality of bit lines parallel extending in a first direction and comprising at least one first bit line and a plurality of second bit lines, the at least one first bit line being disposed at one side of the plurality of second bit lines;
forming a bit line spacer on a sidewall of each of the plurality of second bit lines and a sidewall of the at least one first bit line; and
forming at least one filling layer in the at least one first bit line, the at least one filling layer extending in the first direction and comprising a material being the same as a material of at least a portion of the bit line spacer.

15. The fabricating method of a semiconductor device according to claim 14, forming the plurality of bit lines and the at least one filling layer further comprising:
performing a deposition process, sequentially forming a conductive material layer, a covering material layer and a sacrificial layer on the substrate;
forming a plurality of mask patterns on the sacrificial layer;
forming a photoresist layer on the sacrificial layer, covering a first portion of the mask patterns and exposing a second portion of the mask patterns, wherein a sidewall of the photoresist layer being vertically aligned with a sidewall of the second portion of the mask patterns;
performing a patterning process through the photoresist layer and the second portion of the mask patterns, to simultaneously form the at least one first bit line and the plurality of second bit lines;
forming at least one recess in the at least one first bit line, the at least one recess extending in the first direction; and
after removing the photoresist layer, the plurality of mask patterns and the sacrificial layer, forming the bit line spacer and the at least one filling layer in the at least one recess.

16. The fabricating method of a semiconductor device according to claim 15, wherein forming the at least one recess comprises forming a plurality of recess portion, and the plurality of recess portions comprises different lengths in a second direction perpendicular to the first direction.

17. The fabricating method of a semiconductor device according to claim 16, wherein at least two of the plurality of recess portions are in connection with each other.

18. The fabricating method of a semiconductor device according to claim 16, wherein at least two of the plurality of the recesses are separately from each other.

19. The fabricating method of a semiconductor device according to claim 16, wherein at least two of the plurality of recess portions comprise different depths in a vertical direction perpendicular to the substrate.

20. The fabricating method of a semiconductor device according to claim 19, wherein a bottom surface of at least one of the plurality of recess portions is formed within the conductive material layer or within the covering material layer.
